(19) United States
(12) Patent Application Publication
(10) Pub. No.: US 2013/0200380 A1
(43) Pub. Date: Aug. 8, 2013

(54) ORGANIC ELECTROLUMINESCENT DISPLAY DEVICE

(71) Applicants: Ming-Chieh Chang, Hsinchu County (TW); Po-Hsiao Chen, Tainan City (TW); Chien-Hao Wu, Tainan City (TW); Rong-Bing Wu, Kaohsiung City (TW)

(72) Inventors: Ming-Chieh Chang, Hsinchu County (TW); Po-Hsiao Chen, Tainan City (TW); Chien-Hao Wu, Tainan City (TW); Rong-Bing Wu, Kaohsiung City (TW)

(21) Appl. No.: 13/609,242

(22) Filed: Sep. 10, 2012

(30) Foreign Application Priority Data
Feb. 7, 2012 (CN) 201210027453.4

(51) Int. Cl. H01L 27/15

(52) U.S. Cl. 257/59; 257/72; 257/40; 257/E27.121

(57) ABSTRACT

An organic electroluminescent display device includes a bottom substrate, a covering substrate, a pixel controlling unit, a first organic light emitting unit, and a second organic light emitting unit. The covering substrate is disposed oppositely to the bottom substrate. The pixel controlling unit is disposed between the bottom substrate and the covering substrate. The first organic light emitting unit is disposed between the pixel controlling unit and the covering substrate. The second organic light emitting unit is disposed between the pixel controlling unit and the bottom substrate. The pixel controlling unit is electrically connected to the first organic light emitting unit and the second organic light emitting unit.

### BACKGROUND OF THE INVENTION

1. Field of the Invention

The present invention relates to an organic electroluminescent display device, and more particularly, to an organic electroluminescent display device having organic light emitting units disposed over and under a pixel controlling unit so as to enhance the luminous efficacy, enhance the chromaticity condition, or emit light from both sides of the device.

2. Description of the Prior Art

Because of certain advantages, such as being color filter free, self-lighting, backlight module free, and having low power consumption, the electroluminescent display devices are regarded as a front runner to replace the conventional liquid crystal display devices and become the mainstream display products of the next generation. Organic light emitting diode (OLED) display technology may be the most mature technology among all the electroluminescent display technologies. However, according to developments of related technologies, problems such as low luminous efficacy and high cost are sill hard to be overcome in the organic light emitting diodes. Therefore, related industries still work on modifying other aspects, such as the design of the structure in the display device, so as to enhance the integrated luminous efficacy and the display quality.

### SUMMARY OF THE INVENTION

It is one of the objectives of the present invention to provide an organic electroluminescent display device. Organic light emitting units are disposed over and under a pixel controlling unit. The organic light emitting unit disposed over the pixel controlling unit complements the organic light emitting unit disposed under the pixel controlling unit so as to enhance the integrated luminous efficacy and the chromaticity condition of the organic electroluminescent display device, or to emit light from both sides of the organic electroluminescent display device.

To achieve the purposes described above, a preferred embodiment of the present invention provides an organic electroluminescent display device. The organic electroluminescent display device includes a bottom substrate, a covering substrate, a pixel controlling unit, a first organic light emitting unit, and a second organic light emitting unit. The covering substrate is disposed oppositely to the bottom substrate. The pixel controlling unit is disposed between the bottom substrate and the covering substrate. The first organic light emitting unit is disposed between the pixel controlling unit and the covering substrate. The second organic light emitting unit is disposed between the pixel controlling unit and the bottom substrate. The pixel controlling unit is electrically connected to the first organic light emitting unit and the second organic light emitting unit.

To achieve the purposes described above, a preferred embodiment of the present invention provides an organic electroluminescent display device. The organic electroluminescent display device includes a main substrate, a first covering substrate, a second covering substrate, a first pixel controlling unit, a second pixel controlling unit, a first organic light emitting unit, and a second organic light emitting unit. The main substrate has an upper surface and a lower surface. The first covering substrate is disposed oppositely to the upper surface of the main substrate. The second covering substrate is disposed oppositely to the lower surface of the main substrate. The first pixel controlling unit is disposed on the upper surface of the main substrate, and the second pixel controlling unit is disposed on the lower surface of the main substrate. The first organic light emitting unit is disposed between the first pixel controlling unit and the first covering substrate. The second organic light emitting unit is disposed between the second pixel controlling unit and the second covering substrate. The first organic light emitting unit is used to generate light toward the first covering substrate, and the second organic light emitting unit is used to generate light toward the second covering substrate. The first pixel controlling unit is electrically connected to the first organic light emitting unit, and the second pixel controlling unit is electrically connected to the second organic light emitting unit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematic diagrams illustrating an organic electroluminescent display device according to a first preferred embodiment of the present invention.

FIG. 3 is a schematic diagram illustrating an organic electroluminescent display device according to a second preferred embodiment of the present invention.

FIG. 4 is a schematic diagram illustrating an organic electroluminescent display device according to a third preferred embodiment of the present invention.

FIG. 5 is a schematic diagram illustrating an organic electroluminescent display device according to a fourth preferred embodiment of the present invention.

FIG. 6 is a schematic diagram illustrating an organic electroluminescent display device according to a fifth preferred embodiment of the present invention.

### DETAILED DESCRIPTION

Certain terms are used throughout the description and following claims to refer to particular components. As one skilled in the art will understand, electronic equipment manufacturers may refer to a component by different names. This document does not intend to distinguish components that differ in name but not function. In the following description and in the claims, the term “include” is used in an open-ended fashion, and thus should be interpreted to mean “include, but not limited to . . . ” In addition, to simplify the descriptions and make it more convenient to compare embodiments between each other, identical components are marked with the same reference numerals in each of the following embodiments. Please note that the figures are only for illustration and the figures may not be to scale. Additionally, the terms such as “first” and “second” in this context are only used to distinguish different components and do not constrain the order of generation.

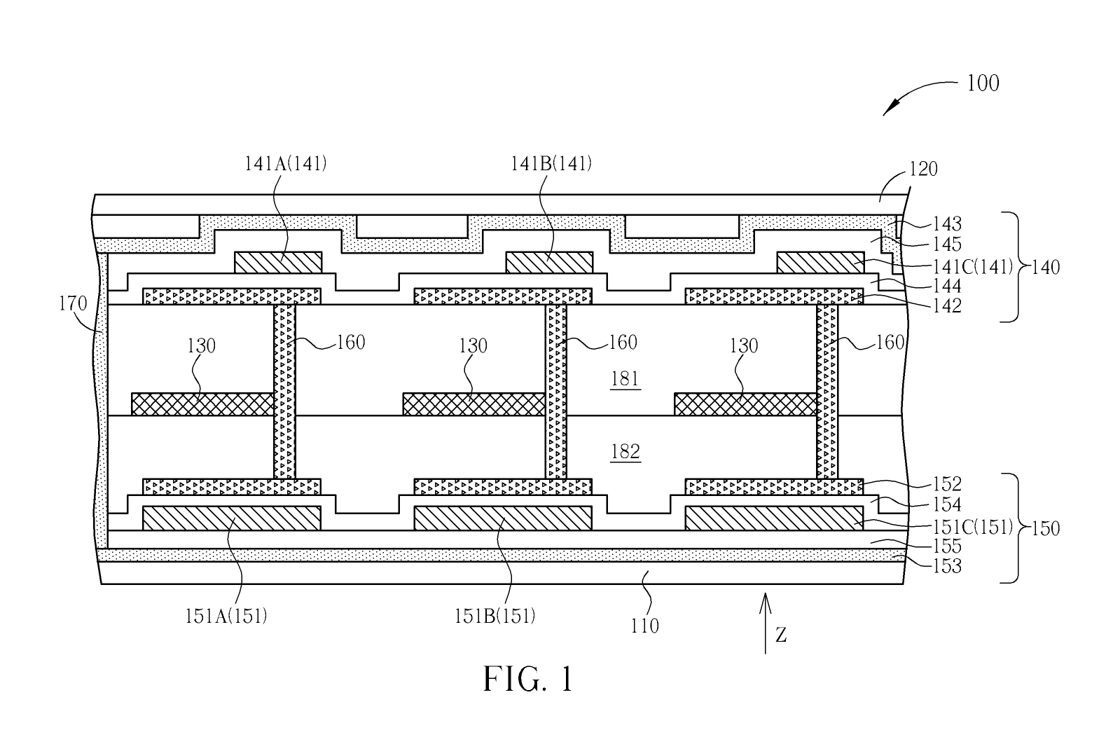

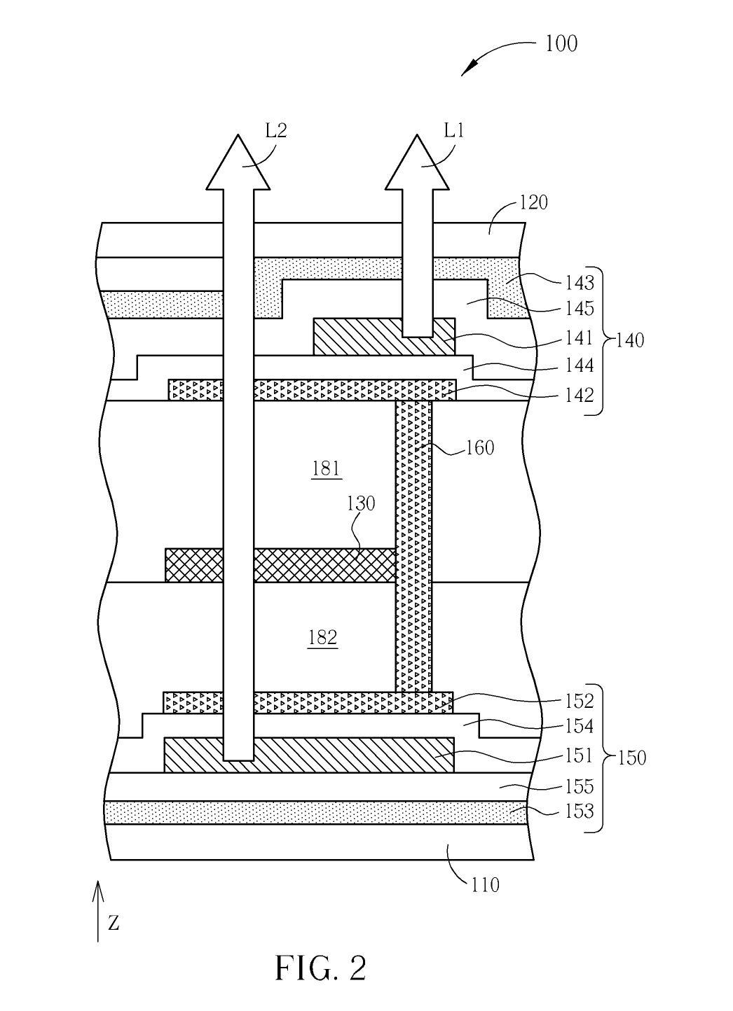

Please refer to FIG. 1 and FIG. 2. FIG. 1 and FIG. 2 are schematic diagrams illustrating an organic electroluminescent display device according to a first preferred embodiment of the present invention. More specifically, FIG. 2 is a schematic diagram illustrating a display condition of the organic electroluminescent display device according to the first preferred embodiment of the present invention. As shown in FIG. 1 and FIG. 2, the first preferred embodiment of the present invention provides an organic electroluminescent display device 100. The organic electroluminescent display device 100 includes a bottom substrate 110, a covering substrate 120, a plurality of pixel controlling units 130, a plurality of first organic light emitting units 140, and a plurality of second organic light emitting units 150. The covering substrate 120 is disposed oppositely to the bottom substrate 110. The pixel controlling units 130 are disposed between the bottom substrate 110 and the covering substrate 120. Each of the first organic light emitting units 140 is disposed between the corresponding pixel controlling unit 130 and the covering substrate 120. Each of the second organic light emitting units 150 is disposed between the corresponding pixel controlling unit 130 and the bottom substrate 110. Each of the pixel controlling units 130 is electrically connected to one first organic light emitting unit 140 and one second organic light emitting unit 150 so as to control the first organic light emitting unit 140 and the second organic light emitting unit 150 disposed oppositely along a direction Z perpendicular to the bottom substrate 110.

In this embodiment, each of the first organic light emitting units 140 may include a first anode electrode 142, a first cathode electrode 143, and a first organic light emitting layer 141. The first organic light emitting layer 141 is disposed between the first anode electrode 142 and the first cathode electrode 143. Each of the second organic light emitting units 150 may include a second anode electrode 152, a second cathode electrode 153, and a second organic light emitting layer 151. The second organic light emitting layer 151 is disposed between the second anode electrode 152 and the second cathode electrode 153. Additionally, the organic electroluminescent display device 100 in this embodiment further includes a plurality of first connecting lines 160. Each of the connecting lines 160 is disposed between the first organic light emitting unit 140 and the corresponding second organic light emitting unit 150. Each of the pixel controlling units 130 may be electrically connected to the first organic light emitting unit 140 and the second organic light emitting unit 150 through the corresponding connecting line 160 so as to control the first organic light emitting unit 140 and the second organic light emitting unit 150 disposed oppositely along the direction Z. It is worth noting that, in this embodiment, each of the first organic light emitting units 140 and each corresponding second organic light emitting unit 150 are connected in parallel. For example, each of the pixel controlling units 130 may be electrically connected to the corresponding first organic light emitting unit 140 and the corresponding light emitting unit 150 through the connecting line 160, and the first organic light emitting unit 140 and the corresponding light emitting unit 150 may be connected in parallel through the corresponding connecting line 160. An identical signal may be transmitted from the pixel controlling unit 130 to the corresponding first organic light emitting unit 140 and the corresponding second organic light emitting unit 150. The first organic light emitting unit 140 and the second organic light emitting unit 150 may be driven by the identical signal, and the luminous conditions of the first organic light emitting unit 140 and the second organic light emitting unit 150 may be controlled by the corresponding pixel controlling unit 130. In addition, the organic electroluminescent display device 100 in this embodiment may further include a second connecting line 170 disposed between the first cathode electrode 143 and the second cathode electrode 153. The first cathode electrode 143 may be electrically connected to the second cathode electrode 153 through the second connecting line 170. Differences between the luminous condition of the first organic light emitting unit 140 and the luminous condition of the corresponding second organic light emitting unit 150 may be accordingly minimized, and the related driving approach may also be accordingly simplified. In this embodiment, each of the pixel controlling units 130 may be a switching circuit, and each of the pixel controlling units 130 may include an oxide semiconductor thin film transistor, an amorphous silicon thin film transistor, a poly silicon thin film transistor, or an organic semiconductor thin film transistor, but not limited thereto.

Based on the structure and the allocation approach described above, the first organic light emitting unit 140 may generate a light L1 toward the covering substrate 120, and the second organic light emitting unit 150 may generate a light L2 toward the covering substrate 120. In this embodiment, a color of the light L1 generated by the first organic light emitting unit 140 may be identical to a color of the light L2 generated by the second organic light emitting unit 150 so as to contribute to a better luminous efficacy of the organic electroluminescent display device 100, but the present invention is not limited to this. The color of the light L1 may also be different from the color of the light L2 so as to contribute to a better white balance performance and enhance a chromaticity condition of the organic electroluminescent display device 100. Additionally, each of the first organic light emitting layer 141 and the corresponding second organic light emitting layer 151 may only partially overlap with each other along the direction Z perpendicular to the bottom substrate 110 so as to lower an influence of the first organic light emitting unit 140 on the light L2 generated from the second organic light emitting unit 150. It is worth noting that the organic electroluminescent display device 100 in this embodiment may further include a first organic light emitting layer 141A, a first organic light emitting layer 141B, and a first organic light emitting layer 141C respectively disposed in different first organic light emitting units 140. The first organic light emitting layer 141A, the first organic light emitting layer 141B, and the first organic light emitting layer 141C may be used to generate light with different colors. Light generated from the first organic light emitting layer 141A, the first organic light emitting layer 141B, and the first organic light emitting layer 141C may be mixed to provide a full color display effect. Comparatively, the organic electroluminescent display device 100 in this embodiment may further include a second organic light emitting layer 151A, a second organic light emitting layer 151B, and a second organic light emitting layer 151C respectively disposed in different second organic light emitting units 150. Colors of light generated from the second organic light emitting layer 151A, the second organic light emitting layer 151B, and the second organic light emitting layer 151C may be modified to accompany the corresponding first organic layer 141. The above-mentioned purposes of enhancing the luminous efficacy or enhancing the chromaticity condition through white balance compensation may be therefore achieved.

In this embodiment, each of the first organic light emitting units 140 may further include a transporting layer 144 and a transporting layer 145. The transporting layer 144 is disposed between the first organic light emitting layer 141 and the first anode electrode 142, and the transporting layer 145 is disposed between the first organic light emitting layer 141 and the first cathode electrode 143. Each of the second organic light emitting units 150 may further include a transporting layer 154 and a transporting layer 155. The transporting layer 154 is disposed between the second organic light emitting layer 151 and the second anode electrode 152, and the transporting 155 is disposed between the second organic light emitting layer 151 and the second cathode electrode 153. The transporting layer 144, the transporting layer 145, the transporting layer 154, and the transporting layer 155 may respectively be an electron transporting layer or a hole transporting layer according to different design combinations, but not limited thereto. In addition, the organic electroluminescent display device 100 may further include a first insulating layer 181 and a second insulating layer 182. The first insulating layer 181 is disposed between the pixel controlling unit 130 and the first organic light emitting unit 140, and the second insulating layer 182 is disposed between the pixel controlling unit 130 and the second organic light emitting unit 150. The first insulating layer 181 and the second insulating layer 182 may include inorganic materials, such as silicon nitride, silicon oxide, or silicon oxynitride, organic materials, such as acrylic resin, or other appropriate materials. Additionally, the first organic light emitting units 140 and the second organic light emitting units 150 may be top emission organic light emitting display units, but not limited thereto.

The following description will detail the different embodiments of the organic electroluminescent display device in the present invention. To simplify the description, identical components in each of the following embodiments are marked with identical symbols. For making it easier to understand the differences between the embodiments, the following description will detail the dissimilarities among different embodiments and the identical features will not be redundantly described.

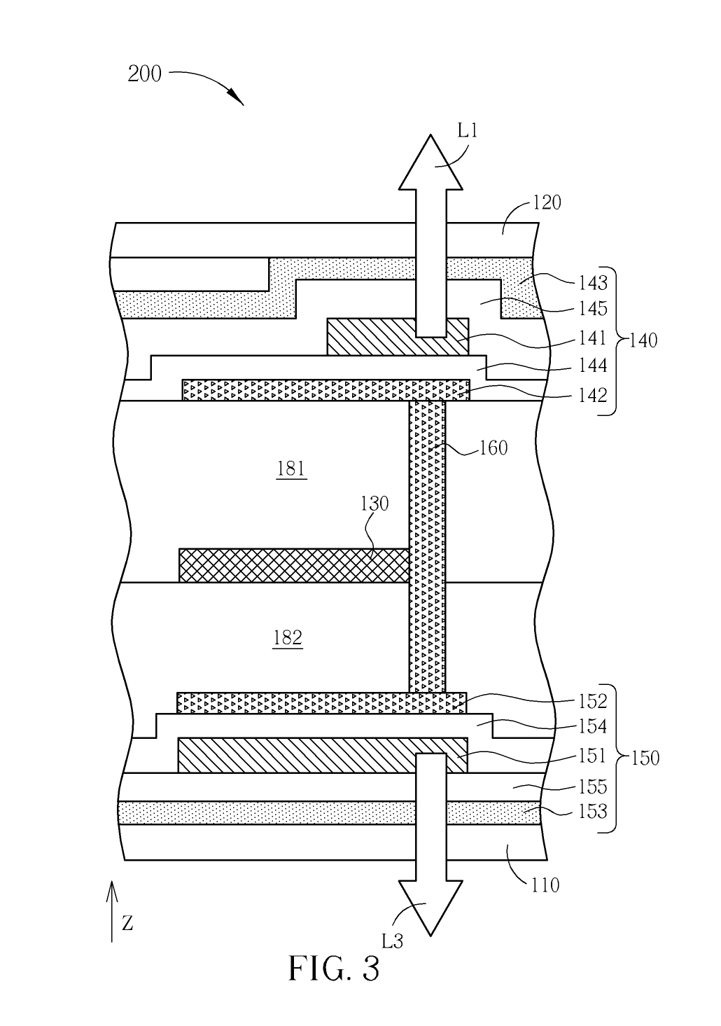

Please refer to FIG. 3. FIG. 3 is a schematic diagram illustrating an organic electroluminescent display device according to a second preferred embodiment of the present invention. As shown in FIG. 3, the difference between an organic electroluminescent display device 200 of this embodiment and the organic electroluminescent display device 100 of the first preferred embodiment detailed above is that the second organic light emitting unit 150 in this embodiment may be used to generate a light L3 toward the bottom substrate 110. The light L3 may cooperate with the light L1 generated from the first organic light emitting unit 140, and the organic electroluminescent display device 200 may then emit light from both sides of the device. Apart from the light L3 in this embodiment, the other components, allocations, and material properties in this embodiment are similar to those of the organic electroluminescent display device 100 in the first preferred embodiment detailed above and will not be redundantly described.

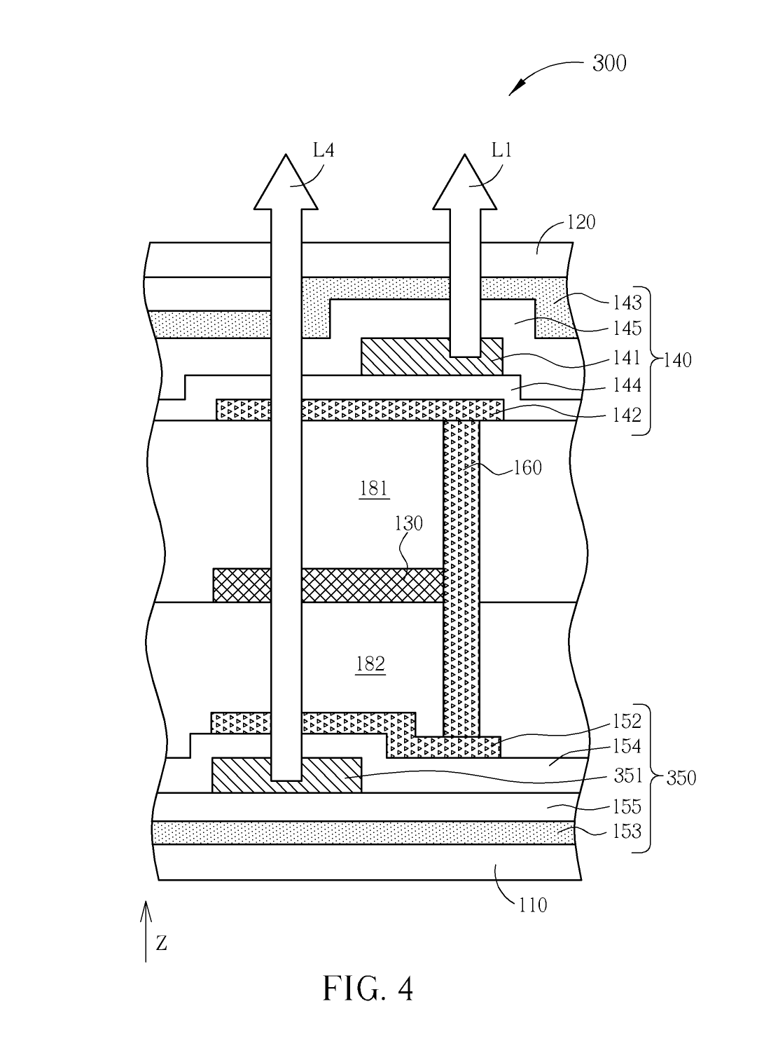

Please refer to FIG. 4. FIG. 4 is a schematic diagram illustrating an organic electroluminescent display device according to a third preferred embodiment of the present invention. As shown in FIG. 4, an organic electroluminescent display device 300 in this embodiment includes a bottom substrate 110, a covering substrate 120, a pixel controlling unit 130, a first organic light emitting unit 140, and a second organic light emitting unit 350. The second organic light emitting unit 350 includes a second anode electrode 152, a second cathode electrode 153, and a second organic light emitting layer 351. The second organic light emitting layer 351 is disposed between the second anode electrode 152 and the second cathode electrode 153. The difference between the organic electroluminescent display device 300 of this embodiment and the organic electroluminescent display device 100 of the first preferred embodiment detailed above is that the first organic light emitting layer 141 and the second organic light emitting layer 351 do not overlap each other along the direction Z perpendicular to the bottom substrate 110, and a light L4 generated from the second organic light emitting layer 351 may not be influenced by the position of the first organic light emitting layer 141. Additionally, a color of the light L1 may be identical to a color of the light L4 so as to contribute to a better luminous efficacy of the organic electroluminescent display device 300, but the present invention is not limited to this. The color of the light L1 may also be different from the color of the light L4 so as to contribute to a better white balance performance and enhance a chromaticity condition of the organic electroluminescent display device 300. Apart from the second organic light emitting layer 351 in this embodiment, the other components, allocations, and material properties in this embodiment are similar to those of the organic electroluminescent display device 100 in the first preferred embodiment detailed above and will not be redundantly described. In this embodiment, the second organic light emitting unit 350 may also be used to generate light toward the bottom substrate (not shown), which is similar to the second preferred embodiment detailed above, and the organic electroluminescent display device 300 may then emit light from dual sides.

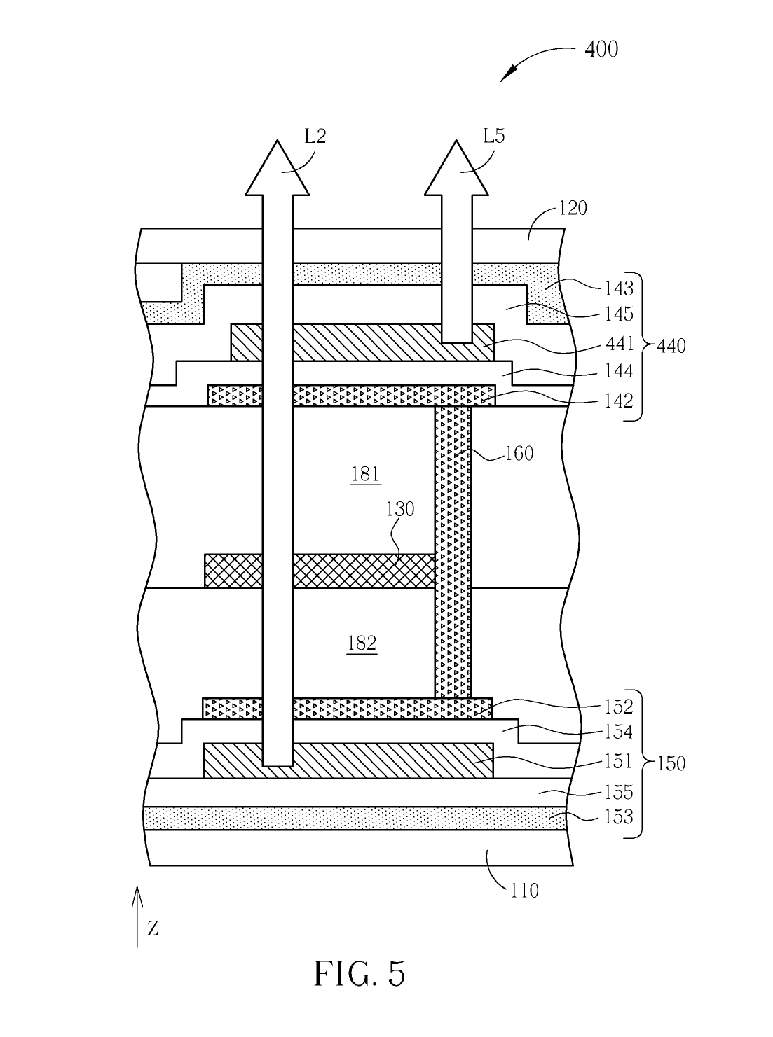

Please refer to FIG. 5. FIG. 5 is a schematic diagram illustrating an organic electroluminescent display device according to a fourth preferred embodiment of the present invention. As shown in FIG. 5, an organic electroluminescent display device 400 in this embodiment includes a bottom substrate 110, a covering substrate 120, a pixel controlling unit 130, a first organic light emitting unit 440, and a second organic light emitting unit 150. The first organic light emitting units 440 includes a first anode electrode 142, a first cathode electrode 143, and a first organic light emitting layer 441. The first organic light emitting layer 441 is disposed between the first anode electrode 142 and the first cathode electrode 143. The difference between the organic electroluminescent display device 400 of this embodiment and the organic electroluminescent display device 100 of the first preferred embodiment detailed above is that the first organic light emitting layer 441 and the second organic light emitting layer 151 overlap each other along the direction Z perpendicular to the bottom substrate 110 so as to further enhance a compensation effect of the light L2 generated from the second organic light emitting layer 151 on a light L5 generated from the first organic light emitting layer 441. In addition, a color of the light L2 may be identical to a color of the light L5 so as to contribute to a better luminous efficacy of the organic electroluminescent display device 400, but the present invention is not limited to this. The color of the light L2 may also be different from the color of the light L5 so as to contribute to a better white balance performance and enhance a chromaticity condition of the organic electroluminescent display device 400. Apart from the first organic light emitting layer 441 in this embodiment, the other components, allocations, and material properties in this embodiment are similar to those of the organic electroluminescent display device 100 in the first preferred embodiment detailed above and will not be redundantly described. In this embodiment, the second organic light emitting unit 150 may also be used to generate light toward the bottom substrate (not shown), which is similar to the second preferred embodiment detailed above, and the organic electroluminescent display device 400 may then emit light from dual sides.

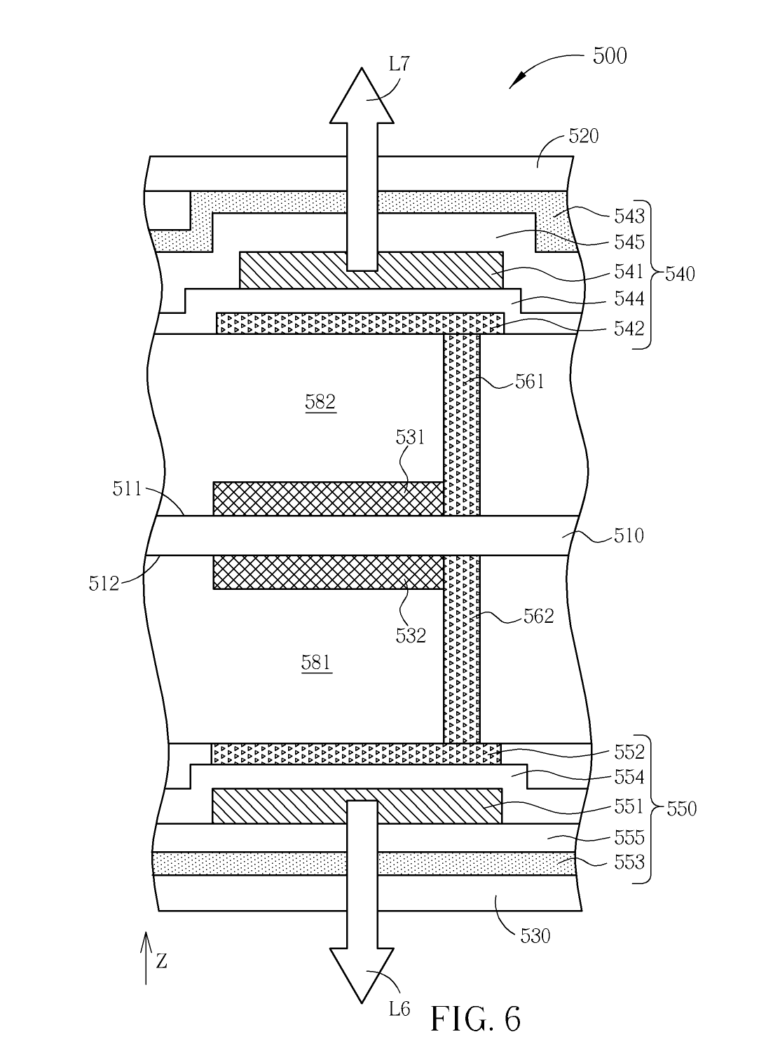

Please refer to FIG. 6. FIG. 6 is a schematic diagram illustrating an organic electroluminescent display device according to a fifth preferred embodiment of the present invention. As shown in FIG. 6, an organic electroluminescent display device 500 in this embodiment includes a main substrate 510, a first covering substrate 520, a second covering substrate 530, a first pixel controlling unit 531, a second pixel controlling unit 532, a first organic light emitting unit 540, and a second organic light emitting unit 550. The main substrate 510 has an upper surface 511 and a lower surface 512. The first covering substrate 520 is disposed oppositely to the upper surface 511 of the main substrate 510. The second covering substrate 530 is disposed oppositely to the lower surface 512 of the main substrate 510. The first pixel controlling unit 531 is disposed on the upper surface 511 of the main substrate 510, and the second pixel controlling unit 532 is disposed on the lower surface 512 of the main substrate 510. The first organic light emitting unit 540 is disposed between the first pixel controlling unit 531 and the first covering substrate 520. The second organic light emitting unit 550 is disposed between the second pixel controlling unit 532 and the second covering substrate 530. The first organic light emitting unit 540 is used to generate light toward the first covering substrate 520, and the second organic light emitting unit 550 is used to generate light toward the second covering substrate 530. The first pixel controlling unit 531 is electrically connected to the first organic light emitting unit 540, and the second pixel controlling unit 532 is electrically connected to the second organic light emitting unit 550.

In this embodiment, the first organic light emitting units 540 may include a first anode electrode 542, a first cathode electrode 543, and a first organic light emitting layer 541. The first organic light emitting layer 541 is disposed between the first anode electrode 542 and the first cathode electrode 543. Each of the second organic light emitting units 550 may include a second anode electrode 552, a second cathode electrode 553, and a second organic light emitting layer 551. The second organic light emitting layer 551 is disposed between the second anode electrode 552 and the second cathode electrode 553. Additionally, the organic electroluminescent display device 500 in this embodiment may further include a third connecting line 561 and a fourth connecting line 562. The third connecting line 561 is disposed between the first organic light emitting unit 540 and the main substrate 510 so as to electrically connect the first pixel controlling unit 531 and the first organic light emitting unit 540. The fourth connecting line 562 is disposed between the second organic light emitting unit 550 and the main substrate 510 so as to electrically connect the second pixel controlling unit 532 and the second organic light emitting unit 550. In this embodiment, the first pixel controlling unit 531 and the second pixel controlling unit 532 respectively include an oxide semiconductor thin film transistor, an amorphous silicon thin film transistor, a poly silicon thin film transistor, or an organic semiconductor thin film transistor, but not limited thereto. The main substrate 510 in this embodiment may include a flexible substrate, such as a plastic substrate or other substrates made of appropriate materials, and the organic electroluminescent display device 500 may accordingly become flexible. Based on the structure and the allocation approach described above, the first organic light emitting unit 540 may generate a light L7 toward the first covering substrate 520, the second organic light emitting unit 550 may generate a light L6 toward the second covering substrate 530, and the organic electroluminescent display device 500 may then emit light from both sides of the device.

In this embodiment, the first organic light emitting unit 540 may further include a transporting layer 544 and a transporting layer 545. The transporting layer 544 is disposed between the first organic light emitting layer 541 and the first anode electrode 542, and the transporting layer 545 is disposed between the first organic light emitting layer 541 and the first cathode electrode 543. The second organic light emitting unit 550 may further include a transporting layer 554 and a transporting layer 555. The transporting layer 554 is disposed between the second organic light emitting layer 551 and the second anode electrode 552, and the transporting 555 is disposed between the second organic light emitting layer 551 and the second cathode electrode 553. The transporting layer 544, the transporting layer 545, the transporting layer 554, and the transporting layer 555 may respectively be an electron transporting layer or a hole transporting layer according to different design combinations, but not limited thereto. In addition, the organic electroluminescent display device 500 may further include a first insulating layer 581 and a second insulating layer 582. The first insulating layer 581 is disposed between the main substrate 510 and the first organic light emitting unit 540, and the second insulating layer 582 is disposed between the main substrate 510 and the second organic light emitting unit 550. Apart from the first pixel controlling unit 531 and the second pixel controlling unit 532, which are used to respectively control the first organic light emitting unit 540 and the second organic light emitting unit 550, in this embodiment, the other components, allocations, and material properties in this embodiment are similar to those of the organic electroluminescent display device 100 in the first preferred embodiment detailed above and will not be redundantly described.

To summarize the above descriptions, in the organic electroluminescent display device of the present invention, the organic light emitting units are disposed over and under the pixel controlling unit. The colors and the directions of the light generated from the organic light emitting units are modified to enhance the integrated luminous efficacy and the chromaticity condition of the organic electroluminescent display device, or to emit light from both sides of the organic electroluminescent display device.

Those skilled in the art will readily observe that numerous modifications and alterations of the device and method may be made while retaining the teachings of the invention. Accordingly, the above disclosure should be construed as limited only by the metes and bounds of the appended claims.

1. An organic electroluminescent display device, comprising:
a bottom substrate;
a covering substrate, disposed oppositely to the bottom substrate;
a pixel controlling unit, disposed between the bottom substrate and the covering substrate;
a first organic light emitting unit, disposed between the pixel controlling unit and the covering substrate; and
a second organic light emitting unit, disposed between the pixel controlling unit and the bottom substrate,
wherein the pixel controlling unit is electrically connected to the first organic light emitting unit and the second organic light emitting unit.

2. The organic electroluminescent display device of claim 1, wherein the first organic light emitting unit and the second organic light emitting unit are connected in parallel.

3. The organic electroluminescent display device of claim 1, wherein a color of light generated by the first organic light emitting unit is identical to a color of light generated by the second organic light emitting unit.

4. The organic electroluminescent display device of claim 1, wherein a color of light generated by the first organic light emitting unit is different from a color of light generated by the second organic light emitting unit.

5. The organic electroluminescent display device of claim 1, wherein the first organic light emitting unit comprises a first organic light emitting layer, the second organic light emitting unit comprises a second organic light emitting layer, and the first organic light emitting layer and the second organic light emitting layer do not overlap each other along a direction perpendicular to the bottom substrate.

6. The organic electroluminescent display device of claim 1, wherein the first organic light emitting unit comprises a first organic light emitting layer, the second organic light emitting unit comprises a second organic light emitting layer, and the first organic light emitting layer and the second organic light emitting layer at least partially overlap each other along a direction perpendicular to the bottom substrate.

7. The organic electroluminescent display device of claim 1, wherein the first organic light emitting unit comprises a first cathode electrode, the second organic light emitting unit comprises a second cathode electrode, and the first cathode electrode is electrically connected to the second cathode electrode.

8. The organic electroluminescent display device of claim 1, wherein the pixel controlling unit comprises an oxide semiconductor thin film transistor, an amorphous silicon thin film transistor, a poly silicon thin film transistor, or an organic semiconductor thin film transistor.

9. An organic electroluminescent display device, comprising:
a main substrate, having an upper surface and a lower surface;
a first covering substrate, disposed oppositely to the upper surface of the main substrate;
a second covering substrate, disposed oppositely to the lower surface of the main substrate;
a first pixel controlling unit, disposed on the upper surface of the main substrate;
a second pixel controlling unit, disposed on the lower surface of the main substrate;
a first organic light emitting unit, disposed between the first pixel controlling unit and the first covering substrate, wherein the first organic light emitting unit is used to generate light toward the first covering substrate; and
a second organic light emitting unit, disposed between the second pixel controlling unit and the second covering substrate, wherein the second organic light emitting unit is used to generate light toward the second covering substrate,
wherein the first pixel controlling unit is electrically connected to the first organic light emitting unit, and the second pixel controlling unit is electrically connected to the second organic light emitting unit.

10. The organic electroluminescent display device of claim 9, wherein the main substrate comprises a flexible substrate.

11. The organic electroluminescent display device of claim 9, wherein the first pixel controlling unit and the second pixel controlling unit respectively comprise an oxide semiconductor thin film transistor, an amorphous silicon thin film transistor, a poly silicon thin film transistor, or an organic semiconductor thin film transistor.
